(19) United States
(12) Patent Application Publication
(10) Pub. No.: US 2026/0082757 A1
(43) Pub. Date: Mar. 19, 2026

(54) LIGHT EMITTING APPARATUS

(71) Applicant: SEOUL VIOSYS CO., LTD., Ansan-si (KR)

(72) Inventor: Ki Yon PARK, Ansan-si (KR)

(73) Assignee: SEOUL VIOSYS CO., LTD., Ansan-si (KR)

(21) Appl. No.: 19/308,948

(22) Filed: Aug. 25, 2025

Related U.S. Application Data
(60) Provisional application No. 63/689,817, filed on Sep. 2, 2024.
(60) Provisional application No. 63/855,596, filed on Aug. 1, 2025.

(51) Int. Cl. H10H 29/856; H10H 29/85

(52) U.S. Cl. CPC H10H 29/856; H10H 29/8506

(57) ABSTRACT

A light emitting apparatus is provided including a light emitting unit and a substrate in which the light emitting unit is disposed, wherein the light emitting unit generates light so that a main emission direction faces a horizontal direction parallel to the substrate.

### CROSS-REFERENCE TO RELATED APPLICATIONS

The present application is related to and claims the benefit of priority from U.S. Provisional Application No. 63/689,817, filed on Sep. 2, 2024, and U.S. Provisional Application No. 63/855,596, filed on Aug. 1, 2025, the entire contents of which are incorporated herein by reference.

### TECHNICAL FIELD

The present invention relates to a light emitting apparatus.

### BACKGROUND

Recently, in a light emitting apparatus, a light emitting diode (LED) is being widely used. The light emitting diode converts an electrical signal into a form of light, such as infrared light, visible light, or ultraviolet light, by using the properties of a compound semiconductor.

As the light efficiency of the light emitting diode increases, a light emitting device is being applied to various fields including a display device, a lighting apparatus, a lamp for a vehicle, and a ship. However, as the light emitting device is used in various applications, the demand for the light emitting device with enhanced luminous efficiency and thermal dissipation performance is increasing.

### SUMMARY

One embodiment of the present invention may generate light that can be used for the removal of harmful organisms by efficiently reflecting light.

One embodiment of the present invention may provide a light emitting apparatus capable of preventing marine organisms from adhering to ships by inducing an avoidance response through efficient light reflection.

One embodiment of the present invention may provide a light emitting apparatus capable of attracting insects by inducing their inflow through efficient light reflection.

One embodiment of the present invention may provide a light emitting apparatus capable of efficiently emitting light by increasing a light extraction efficiency.

One embodiment of the present invention may provide a light emitting apparatus with an improved reliability and increased heat dissipation efficiency by efficiently dissipating heat.

In addition, one embodiment of the present invention may provide a light emitting apparatus with improved luminance by adjusting a refraction direction.

In accordance with one aspect of the present invention, there may be provided a light emitting apparatus, including a light emitting unit; and a substrate in which the light emitting unit is disposed, wherein the light emitting unit generates light so that a main emission direction faces a horizontal direction parallel to the substrate.

Further, there may be provided the light emitting apparatus in which the light emitting unit includes a plurality of light emitting devices, and the plurality of light emitting devices includes a first light emitting device that emits visible light, and a second light emitting device that emits ultraviolet light

Further, there may be provided the light emitting apparatus in which the first light emitting device is disposed at a center of the substrate, and the second light emitting device is disposed in a direction facing a side of the first light emitting device.

Further, there may be provided the light emitting apparatus in which the first light emitting device is arranged to emit the light in a first direction parallel to the substrate, and the second light emitting device is arranged to emit the light in a second direction that is parallel to the substrate and crosses to the first direction.

Further, there may be provided the light emitting apparatus in which the second light emitting device is disposed in a direction facing a side of the first light emitting device.

Further, there may be provided the light emitting apparatus in which the light emitting unit includes: a device substrate; and a terminal electrically connecting the device substrate and the substrate.

Further, there may be provided the light emitting apparatus in which the light emitting unit further includes a second frame on which the device substrate is disposed, and the terminal has a shape surrounding one edge of the device substrate and one edge of the second frame.

Further, there may be provided the light emitting apparatus in which the light emitting unit includes: a light emitting device; a device substrate on which the light emitting device is mounted; and a first frame on which the device substrate is disposed, wherein the first frame is provided with a reflector that reflects light emitted from the light emitting device.

Further, there may be provided the light emitting apparatus in which the reflector has a circular shape surrounding the light emitting device.

Further, there may be provided the light emitting apparatus in which the light emitting unit further includes: a light emitting device; a first reflection layer on which the light emitting device is disposed and which is configured to reflect light; a transmission layer disposed above the light emitting device and configured to transmit light; and a second reflection layer disposed to be spaced apart from the light emitting device by the transmission layer and configured to reflect light.

Further, there may be provided the light emitting apparatus in which a reflectivity of the second reflection layer is equal to or greater than a reflectivity of the first reflection layer, a height of the first reflection layer is less than a separation distance between the light emitting device and the second reflection layer, the height of the first reflection layer is less than a height of the transmission layer, a height of the second reflection layer is less than the height of the transmission layer, a length of the first reflection layer in the horizontal direction is greater than a length of the light emitting device in the horizontal direction, and the length of the first reflection layer in the horizontal direction is less than a length of the transmission layer in the horizontal direction.

Further, there may be provided the light emitting apparatus in which the light emitting unit further includes: a light emitting device; a transmission layer disposed above the plurality of light emitting devices to transmit light; a first reflection layer on which the plurality of light emitting devices are disposed and which reflects light, wherein the transmission layer is arranged to be spaced apart from the light emitting device; and a spacer that scatters light, wherein a separation distance between the light emitting device and the spacer is greater than a length of the first reflection layer in the horizontal direction.

Further, there may be provided the light emitting apparatus in which the light emitting unit further includes: a plurality of light emitting devices; a first reflection layer on which the plurality of light emitting devices are arranged; a transmission layer disposed above the plurality of light emitting devices to transmit light; and a plurality of second reflection layers arranged on the transmission layer and spaced apart from the plurality of light emitting devices and to reflect light.

Further, there may be provided the light emitting apparatus in which the light emitting device further includes: a light emitting structure that generates light; and a light transmission layer laminated on the light emitting structure to transmit the light generated from the light emitting structure, and a height of the first reflection layer is greater than a height of the light emitting structure.

Further, there may be provided the light emitting apparatus in which a separation distance between the light transmission layer and the second reflection layer is greater than the height of the light emitting structure, a height of the light transmission layer is greater than a height of the second reflection layer, the height of the light emitting structure is less than the height of the light transmission layer, and the height of the light emitting structure is less than the height of the second reflection layer.

Further, there may be provided the light emitting apparatus in which the first reflection layer includes a plurality of first reflection layers, the plurality of first reflection layers includes: a first sub-reflection layer elongating in a first direction, and supporting one of the plurality of light emitting devices; and a second sub-reflection layer spaced apart from the first sub-reflection layer in a second direction perpendicular to the first direction, elongated in the first direction, and on which another of the plurality of light emitting devices is disposed, one of the plurality of light emitting devices are spaced apart from each other along the first direction on the first sub-reflection layer, another of the plurality of light emitting devices are spaced apart from each other along the first direction on the second sub-reflection layer, a distance between the light emitting devices in the first direction is smaller than a distance between the light emitting devices in the second direction, and the transmission layers of the plurality of light emitting devices are integrally formed by being connected to each other.

Further, there may be provided a light emitting apparatus, including: a plurality of light emitting units; a substrate on which the plurality of light emitting units are disposed; and a lower reflection layer disposed on the substrate such that at least a portion of the lower reflection layer is located between the plurality of light emitting units, wherein each of the plurality of light emitting units includes: a device substrate; a light emitting device disposed on the device substrate; a first reflection layer disposed between the light emitting device and the device substrate to reflect light; a transmission layer disposed above the light emitting device to transmit light; and a second reflection layer disposed on the transmission layer so as to be spaced apart from the light emitting device to reflect light, and wherein a height of the lower reflection layer is greater than a height of the first reflection layer.

Further, there may be provided a light emitting apparatus, including: a light emitting unit; and a substrate on which the light emitting unit is disposed, wherein the light emitting unit includes a light emitting device, heat generated from the light emitting unit is diffused in a second direction parallel to the substrate and released in a third direction perpendicular to the substrate, and the second direction is perpendicular to the third direction.

Further, there may be provided the light emitting apparatus in which the light emitting unit further includes a device substrate, the device substrate is disposed in a direction perpendicular to the substrate, and the heat is released to an outside along the device substrate

Further, there may be provided a light emitting apparatus including: a light emitting unit; and a substrate on which the light emitting unit is disposed, wherein the light emitting unit emits light in a main emission direction that is parallel to a first direction of the substrate, and is configured to emit the light in a second direction parallel to the substrate, and the first direction is perpendicular to the second direction.

One embodiment of the present invention may generate light that can be used for the removal of harmful organisms by efficiently reflecting light.

Further, efficient reflection of light may induce an avoidance reaction of marine organisms and may prevent marine organisms from attaching to ships.

Further, efficient reflection of light may induce the inflow of insects and may attract insects.

In addition, light extraction efficiency may be increased so that light may be efficiently emitted.

In addition, heat may be dissipated efficiently, so that heat dissipation efficiency may be increased and reliability may be improved.

In addition, luminance may be improved by adjusting a refraction direction.

### BRIEF DESCRIPTION OF THE DRAWINGS'

FIG. 1 is a diagram illustrating a state in which a light emitting apparatus according to a first embodiment of the present invention is mounted on a ship.

FIG. 2 is a diagram illustrating a state in which a second reflection layer of the light emitting apparatus in FIG. 1 is formed to be convex downward.

FIG. 3 is a diagram illustrating a state in which a second reflection layer of the light emitting apparatus in FIG. 2 is formed to be convex upward.

FIG. 4 is a diagram illustrating a state in which a light emitting unit of the light emitting apparatus in FIG. 2 is viewed from above.

FIG. 5 is a diagram illustrating a first example of a light emitting apparatus according to a second embodiment of the present invention.

FIG. 6 is a diagram illustrating a second example of a light emitting apparatus according to the second embodiment of the present invention.

FIG. 7 is a perspective view of a light emitting unit of a light emitting apparatus according to a third embodiment of the present invention.

FIG. 8 is a cross-sectional view taken along A-A′ of the light emitting unit in FIG. 7.

FIG. 9 is a diagram illustrating a state in which a plurality of light emitting devices are disposed on a first reflection layer of a light emitting apparatus according to a fourth embodiment of the present invention.

FIG. 10 is a perspective view of a light emitting apparatus according to a fifth embodiment of the present invention.

FIG. 11 is a cross sectional view taken along line A-A′ of the light emitting apparatus of FIG. 10.

FIG. 12 is an exploded perspective view of the light emitting portion of FIG. 10.

FIG. 13 is a top view showing the arrangement of the light emitting device on a package substrate of FIG. 10.

FIG. 14 is a conceptual diagram of the light emitting device of FIG. 10.

### DETAILED DESCRIPTION

In the following description, for the purposes of explanation, numerous specific details are set forth in order to provide a thorough understanding of various exemplary embodiments or implementations of the present disclosure. As used herein, “embodiments” and “implementations” are interchangeable terms for non-limiting examples of devices or methods employing one or more of the inventive concepts disclosed herein. It will be apparent, however, that various exemplary embodiments may be practiced without these specific details or with one or more equivalent arrangements. In other instances, well-known structures and devices are shown in block diagram form in order to avoid unnecessarily obscuring various exemplary embodiments. Further, various exemplary embodiments may be different, but do not have to be exclusive. For example, specific shapes, configurations, and characteristics of an exemplary embodiment may be used or implemented in another exemplary embodiment without departing from the inventive concepts.

Unless otherwise specified, the illustrated exemplary embodiments are to be understood as providing exemplary features of varying detail of some ways in which the inventive concepts may be implemented in practice. Therefore, unless otherwise specified, the features, components, modules, layers, films, panels, regions, and/or aspects (hereinafter individually or collectively referred to as “elements”) of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, and property of the elements, unless specified. Further, in the accompanying drawings, the size and relative sizes of elements may be exaggerated for clarity and/or descriptive purposes. When an exemplary embodiment is implemented differently, a specific process order may be performed differently from the described order. For example, two consecutively described processes may be performed substantially at the same time or performed in an order opposite the described order. In addition, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the x, y, and z-axes, and may be interpreted in a broader sense. For example, the DR1-axis, the DR2-axis, and the DR3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” and the like may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (for example, as in “sidewall”), and the like, may be used herein for descriptive purposes, and, thereby, to describe one element's relationship to other element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (for example, rotated 90 degrees or at other orientations), and, as such, the spatially relative descriptors used herein may likewise interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various exemplary embodiments are described herein with reference to sectional and/or exploded illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some exemplary embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (for example, microcode) to perform various functions discussed herein and may optionally be driven by firmware and/or software. It is also contemplated that each block, unit, and/or module may be implemented by dedicated hardware, or as a combination of dedicated hardware to perform some functions and a processor (for example, one or more programmed microprocessors and associated circuitry) to perform other functions. Also, each block, unit, and/or module of some exemplary embodiments may be physically separated into two or more interacting and discrete blocks, units, and/or modules without departing from the scope of the inventive concepts. Further, the blocks, units, and/or modules of some exemplary embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure pertains. Terms, such as those defined in commonly used dictionaries, should be interpreted as having a meaning that is consistent with their meaning in the context of the relevant art and should not be interpreted in an idealized or overly formal sense, unless expressly so defined herein.

Hereinafter, a light emitting apparatus 1 according to a first embodiment of the present invention will be described.

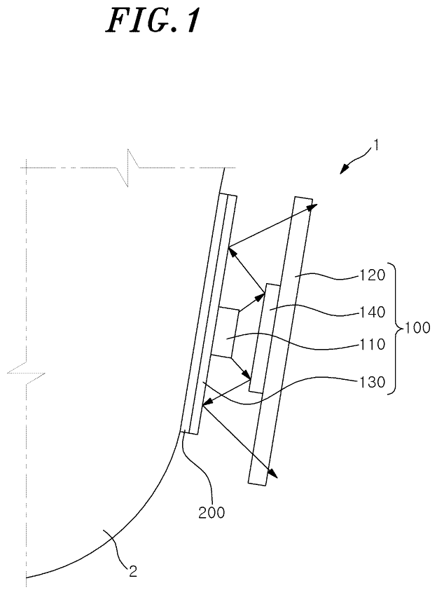

With reference to FIG. 1, the light emitting apparatus 1 according to the first embodiment of the present invention may display letters, symbols, images, or videos. In addition, the light emitting apparatus 1 may be mounted on a vehicle. Such a light emitting apparatus 1 may be included in a rear light, headlamp, rear lamp, tail lamp, or the like. In addition, the light emitting apparatus 1 when mounted on a vehicle may emit light of the red color, light of the yellow color, or light of the white color to display information such as a stop signal or text to the outside.

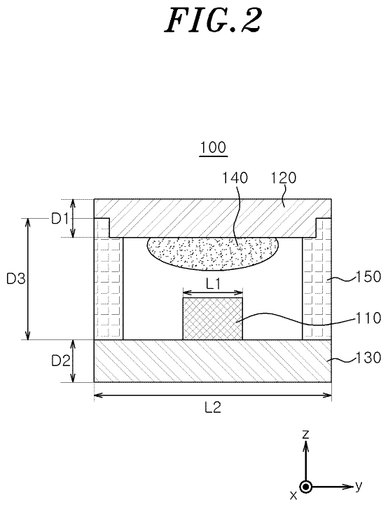

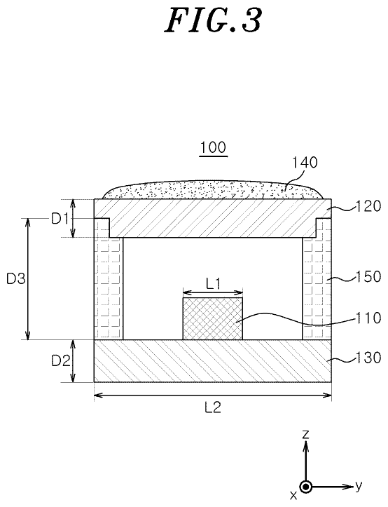

In addition, the light emitting apparatus 1 may be mounted on a ship 2 to generate light in order to prevent marine organisms from attaching to an outer surface of the ship 2. Such a light emitting apparatus 1 may be disposed at a position corresponding to a position of a ballast tank of the ship 2, among outer surfaces of the ship 2. In other words, the light emitting apparatus 1 for ships may be included in the ship 2, and when water flows into or is discharged from the ballast tank of the ship 2, light may be emitted toward marine organisms to prevent them from attaching to the outer surface of the ship 2. The light emitting apparatus 1 may include the light emitting unit 100 and a substrate 200. With further reference to FIGS. 2 and 3, the light emitting unit 100 may generate light. The light emitting unit 100 may be disposed on the substrate 200, and may be connected to an electric circuit of the substrate 200. The light emitting unit 100 may generate light such that a main emission direction thereof is oriented toward a first direction parallel to the substrate 200 (hereinafter referred to as ‘x-axis direction’). The main emission direction may be defined as the direction in which radiant energy emitted from the light emitting device or the light source is maximized per unit solid angle. In other words, the main emission direction may be defined as the direction where the maximum radiant intensity is measured. Furthermore, a viewing angle may be defined as an angular range in which radiant light with an intensity above a certain ratio relative to the main emission direction is distributed. For example, the viewing angle may be the angular range where radiant light with 50% or 80% of the radiant intensity peak relative to the main emission direction is distributed.

In addition, the light emitting unit 100 may emit light in a second direction parallel to the substrate 200 and parallel to the first direction (hereinafter referred to as the ‘y-axis direction’). In other words, the first direction may be perpendicular to the second direction. The emission intensity of light emitted in the first direction parallel to the substrate 200 may be greater than the emission intensity of light emitted in the second direction parallel to the substrate 200 and the first direction.

As light is generated in the light emitting unit 100, heat may also be generated. Heat generated from the light emitting unit 100 may diffuse in the y-axis direction. Also, heat formed in the light emitting unit 100 may be emitted in a direction perpendicular to the substrate 200 (hereinafter referred to as the ‘z-axis direction’).

The main emission direction of light generated from the light emitting unit 100 may be directed toward the x-axis direction. The main diffusion direction of heat generated from the light emitting unit 100 may be parallel to the y-axis direction. The main emission direction of light and the main diffusion direction of heat in the light emitting unit 100 may be formed perpendicular to each other. By having the main emission direction of light and the main diffusion direction of heat perpendicular to each other, optical interference caused by heat generated in the light emitting unit 100 can be reduced.

Furthermore, the main emission direction of heat generated from the light emitting unit 100 may be directed toward the z-axis direction. The main emission direction of light and the main emission direction of heat generated from the light emitting unit 100 may be formed to cross each other. By setting the main emission direction of light and the main emission direction of heat substantially perpendicular, optical interference caused by heat generated in the light emitting unit 100 can be reduced.

In addition, the main diffusion direction of heat and the main emission direction of light generated from the light emitting unit 100 may be formed to cross each other. By forming the main diffusion direction and the main emission direction of heat substantially perpendicular, the light emitting unit 100 can secure thermal capacity and reduce a bottleneck phenomena inside the light emitting unit 100, thereby improving the reliability of the light emitting apparatus 1. The light emitting unit 100 may be formed in plural.

The plurality of light emitting units 100 may be disposed adjacent to each other and may generate light respectively. For example, the plurality of light emitting units 100 may be disposed in N rows and M columns, and may generate light respectively. In other words, the plurality of light emitting units 100 may be arranged in an N×M matrix and may generate light respectively. The number of rows, N, and the number of columns, M, of the plurality of light emitting units 100 may be the same or different. In addition, each light emitting unit 100 may be individually driven by region to adjust luminance or adjust a light emitting region. The light emitting unit 100 may generate blue light, green light, red light, white light, UV light, and the like. By light generated from such a light emitting unit 100, attachment of marine organisms to the ship 2 may be prevented. The light emitting unit 100 may include a light emitting device 110, a transmission layer 120, a first reflection layer 130, a second reflection layer 140, and a spacer 150.

The light emitting device 110 may generate light. The light emitting device 110 may be electrically connected to an electric circuit of the substrate 200 and may generate light by receiving electricity from the outside through the electric circuit. The light emitting device 110 may be disposed between the first reflection layer 130 and the transmission layer 120. In other words, the light emitting device 110 may be disposed by the first reflection layer 130 and may emit light toward the transmission layer 120. The light emitting device 110 may be disposed to be spaced apart in a vertical direction from the second reflection layer 140 and the transmission layer 120.

A length L1 in a horizontal direction (y-axis direction in FIG. 2) of the light emitting device 110 may be smaller than a length L2 in a horizontal direction of the first reflection layer 130 and a length L2 in a horizontal direction of the transmission layer 120. A height of the light emitting device 110 may be greater than one or more of a height D1 of the transmission layer 120 or a height D2 of the first reflection layer 130. The height of the light emitting device 110 may be greater than a height (z-axis direction length in FIG. 2) of the second reflection layer 140, and through this, a side light extraction efficiency of the light emitting device may be increased.

The transmission layer 120 may transmit light of the light emitting device 110. The transmission layer 120 may be disposed to be spaced apart upward from the light emitting device 110. For example, the transmission layer 120 may be formed of quartz, silicon, glass, ceramic, or the like. The length L2 in a horizontal direction of the transmission layer 120 may be greater than a length in a horizontal direction of the second reflection layer 140. The height D1 of the transmission layer 120 may be greater than the height D2 of the first reflection layer 130. In addition, the height D1 of the transmission layer 120 may be greater than the height of the second reflection layer 140, and may prevent damage to the second reflection layer from an external environment.

The first reflection layer 130 may be disposed below the light emitting device 110 and may reflect light. The first reflection layer 130 may be disposed between the light emitting device 110 and the substrate 200. In other words, the first reflection layer 130 may reflect a portion of light emitted from the light emitting device 110 toward the substrate 200, or light reflected from the second reflection layer 140 toward the substrate 200, toward the transmission layer 120 to increase an amount of light. The first reflection layer 130 and the second reflection layer 140 may be formed to differ from each other in at least one of reflectance, thermal conductivity, or thermal expansion coefficient. Since the first reflection layer 130 may be in contact with the light emitting device 110 and may efficiently dissipate heat of the light emitting device 110, heat dissipation of the light emitting device 110 may be transferred to the outside, and thermal resistance may be reduced, thereby improving reliability of the light emitting unit 100. Reflectance of the first reflection layer 130 may be formed to be smaller than reflectance of the second reflection layer 140. For example, the reflectance of the second reflective layer 140 at the peak wavelength of the emission spectrum of the light emitting device 110 may be 1.5 to 2 times higher than the reflectance of the first reflective layer 130. This can diversify the optical reflection paths and thereby improve the light extraction efficiency. In addition, a thermal expansion coefficient of the first reflection layer 130 may be formed to be smaller than a thermal expansion coefficient of the second reflection layer 140, and thermal shock may be alleviated so that the light emitting device 110 is not detached from the substrate 200.

The length L2 in a horizontal direction of the first reflection layer 130 may be greater than the length L1 in a horizontal direction of the light emitting device 110. The length L2 in a horizontal direction of the first reflection layer 130 may be greater than the length in a horizontal direction of the second reflection layer 140. In addition, the length L2 in a horizontal direction of the first reflection layer 130 may be the same as the length in a horizontal direction of the transmission layer 120, and through this, light directed downward may be reflected upward. However, it is not limited thereto, and the length in a horizontal direction of the first reflection layer 130 may be smaller than the length in a horizontal direction of the transmission layer 120. In addition, the height of the first reflection layer 130 may be greater than the height of the second reflection layer 140, and may increase upward reflectance by securing a sufficient thickness of the first reflection layer. The thickness of the first reflective layer 130 may be greater than a distance between a lower surface and an upper surface of the light emitting device 110. In other words, the thickness of the first reflective layer 130 may be 1.1 to 2 times the thickness of the light emitting device 110 in the height direction. As the thickness of the first reflective layer 130 becomes greater than the thickness of the light emitting device 110, the reflectance toward the upper surface may increase.

With reference to FIG. 2, the second reflection layer 140 may be disposed in one region of the transmission layer 120 to reflect light. As a first example, the second reflection layer 140 may be disposed on a lower surface of the transmission layer 120. In addition, the second reflection layer 140 may be formed to be convex downward, but is not limited thereto, and may also be formed to be concave. In addition, the second reflection layer 140 may have a surface whose slope with respect to the first reflection layer 130 gradually increases as it is spaced farther in a horizontal direction from a center of the light emitting device 110. Through this, a reflection angle may be widened toward a side, thereby achieving a wide emission angle. In addition, a thickness may gradually become thinner as distance from the center of the light emitting device increases, and through this, the transmittance may increase toward a side compared to a center, thereby widening an emission angle of the light emitting unit 100.

With reference to FIG. 3, as a second example, the second reflection layer 140 may be disposed on an upper surface of the transmission layer 120. In addition, the second reflection layer 140 may be formed to be convex upward, but is not limited thereto, and may also be formed to be concave. In addition, a thickness of the second reflection layer 140 may become thinner toward an outer side, and through this, the transmittance may increase toward the outer side, thereby increasing the light transmitted to a side rather than a center and widening an emission angle. In this case, a reflective surface of the second reflection layer 140 facing the light emitting device 110 may have a planar shape, and a processing error may be reduced by making the reflective surface uniform. The second reflection layer 140 may be disposed on the transmission layer 120 so as to be spaced apart from the light emitting device 110. In other words, the second reflection layer 140 may be spaced apart from the light emitting device 110 in a vertical direction. The second reflection layer 140 may include at least one of alumina (Al₂O₃), titanium dioxide (TiO₂), or barium sulfate (BaSO₄) as a reflective filler for increasing reflectance in an organic compound binder such as silicone or epoxy, which serves to stably retain the shape of the light reflected toward the second reflection layer 140. In addition, a plurality of fillers, such as silica or glass fiber, may be further included in an inside of the second reflection layer 140 to increase the strength of the second reflection layer 140. In addition, since the second reflection layer 140 is disposed on the transmission layer 120, a light condensing efficiency (light convergence) of the light emitting device 110 may be further improved, so that a sterilization effect and a curing effect may be improved. The reflectance of the second reflection layer 140 may be equal to or greater than the reflectance of the first reflection layer 130.

The length in a horizontal direction of the second reflection layer 140 may be smaller than one or more of the first reflection layer 130 or the transmission layer 120, so that a portion of light reflected by the second reflection layer 140 may be reflected again upward through the first reflection layer 130, and therefore, light extraction efficiency may be increased. In addition, the height of the second reflection layer 140 may be smaller than one or more of the height D2 of the first reflection layer 130 or the height D1 of the transmission layer 120. In addition, the length in a horizontal direction of the second reflection layer 140 may be smaller than the length in a horizontal direction of the light emitting device 110.

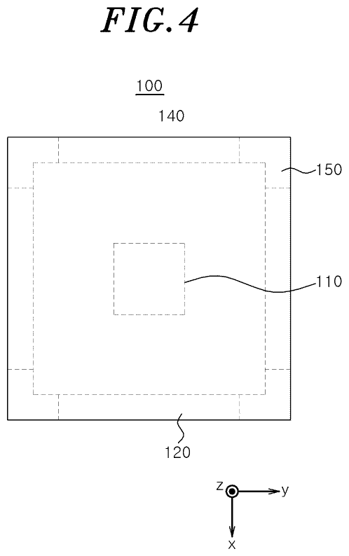

With further reference to FIG. 4, the spacer 150 may be formed to be elongated in a vertical direction and may support the transmission layer 120. The spacer 150 having a height D3 may be disposed between the first reflection layer 130 and the transmission layer 120. In other words, the spacer 150 may extend upward from an upper surface of the first reflection layer 130 and may support the transmission layer 120.

By such a spacer 150, the second reflection layer 140 and the transmission layer 120 may be spaced upward from the light emitting device 110. The spacer 150 may be formed of a light-transmissive material and may scatter light. In other words, light may be scattered while passing through the spacer 150, so that an emission angle of the light emitting unit 100 may be widened. A step may be formed at an upper portion of the spacer 150 to stably support the transmission layer 120. In addition, the spacer 150 may be formed in plural to support an edge of the transmission layer 120. In other words, a plurality of spacers 150 may support corners of the transmission layer 120, and may scatter light of a corner region to increase light uniformity. An edge of the transmission layer 120 may be formed to correspond to a step shape of the spacer 150.

The light emitting unit 100 may be disposed on the substrate 200. For example, the substrate 200 may be a printed circuit board (PCB) substrate in which an electric circuit is printed. In addition, the substrate 200 may be a thin-film transistor (TFT) backplane. The substrate 200 may include one or more of Cu, Zn, Au, Ni, Al, Mg, Cd, Be, W, Mo, Si, Ag, or Fe having electrical conductivity, or an alloy composed of some of them, and thereby electrical and thermal conductivity may be increased. However, this is merely an example, and the substrate 200 may include one or more of insulating materials such as FR1, CEM-1, FR-4, PMMA, PCT, and PPA, and thereby short circuits between respective circuits may be prevented. Here, FR1 is a material in which copper foil and laminate paper are stacked, and CEM-1 is a material in which copper foil, glass fiber woven fabric, laminate paper, and glass fiber woven fabric are sequentially stacked. In addition, FR-4 is a material in which copper foil and glass fiber woven fabric or glass fiber fabric are stacked. In addition, the substrate 200 may include ceramic, such as alumina (Al₂O₃), aluminum nitride (AlN), or zirconia toughened alumina (ZTA).

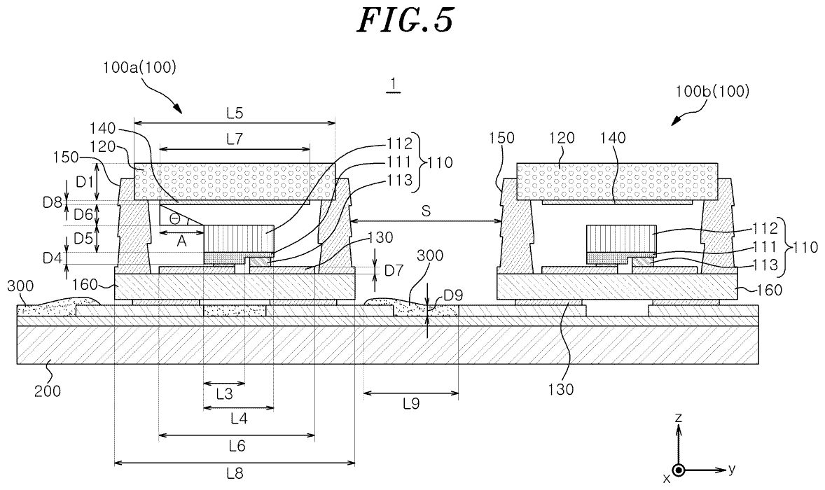

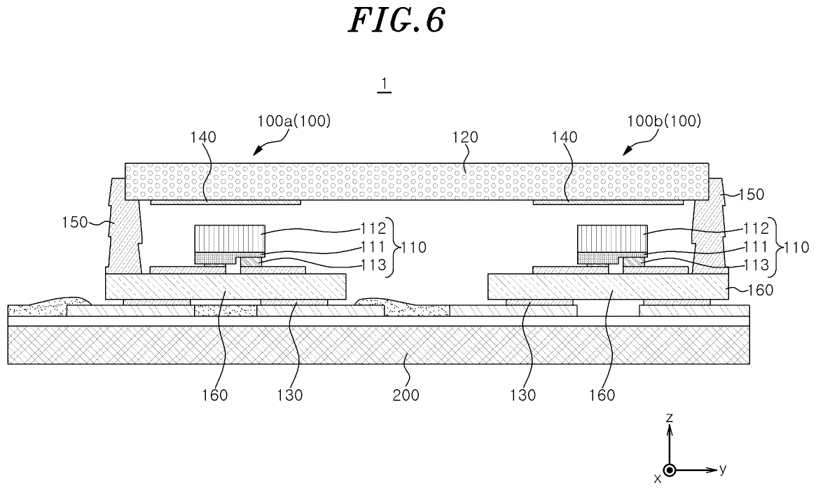

Hereinafter, with reference to FIGS. 5 and 6, a light emitting apparatus 1 according to a second embodiment of the present invention will be described. In describing the second embodiment, a difference lies in that the light emitting unit 100 is formed in plural and the lower reflection layer 300 is further included, and such differences will be mainly described.

With reference to FIG. 5, the plurality of light emitting units 100 may be spaced apart from each other in a horizontal direction on the substrate 200. For example, the plurality of light emitting units 100 may include a first light emitting unit 100a and a second light emitting unit 100b, and a separation distance S between the first light emitting unit 100a and the second light emitting unit 100b may be formed longer than a length L9 in a horizontal direction of the lower reflection layer 300 disposed between the first light emitting unit 100a and the second light emitting unit 100b, which will be described below. Accordingly, the lower reflection layer 300 may reduce light damage, thereby enhancing the reliability of the light emitting apparatus 1. Each light emitting device 110 of the plurality of light emitting units 100 may further include a device substrate 160.

The device substrate 160 may include a substrate base and a conductive pattern. The substrate base may be formed of at least one material of phenol, epoxy, polyimide, or ceramic. That is, a substrate base may be formed of an insulating material. In addition, the substrate base may include a metal layer and an insulating layer formed on a surface of the metal layer. For example, the insulating layer may be an insulating resin including phenol, epoxy, or a fluororesin, or may be a metal or a metal oxide. That is, the substrate base may be formed in a structure that may be insulated from a conductive pattern. In addition, the substrate base is not limited to the above-described material and structure, and may be formed to have various materials or various structures insulated from the conductive pattern.

In addition, the substrate base may further include a ceramic filler. When the substrate base includes the ceramic filler, heat dissipation efficiency of the light emitting apparatus may be improved, and light reflectance of the substrate may be improved.

A conductive pattern may be formed on an upper portion and a lower portion of the substrate base. In addition, the conductive pattern may be further formed in an inside or a side surface of the substrate base to electrically connect a conductive pattern formed on the upper portion of the substrate base and a conductive pattern formed on the lower portion of the substrate base. The conductive pattern may be formed of any material having conductivity. For example, the conductive pattern may be formed of at least one of Cu, W, Ag, Au, Ni, or Pd. When the conductive pattern is metal, heat dissipation efficiency of the light emitting device 110 may be improved.

The conductive pattern of the device substrate 160 may be electrically connected to a light emitting member, and the substrate may supply power to the light emitting device 110 through the conductive pattern.

In addition, the light emitting device 110 may include a light emitting structure 111, a light transmitting layer 112, and an electrode 113.

The light emitting structure 111 may generate light. A total thickness of the light emitting structure 111 may be in a range of 1 μm to 10 μm. The light emitting structure 111 may include a first conductive-type semiconductor layer, an active layer, and a second conductive-type semiconductor layer.

The first conductive-type semiconductor layer may be electrically connected to the device substrate 160. The first conductive-type semiconductor layer may include n-type impurities (e.g., Si, Ge, Sn), and in this case, the first conductive-type semiconductor layer may be an n-type semiconductor layer. However, this is merely an example, and the first conductive-type semiconductor layer may also include p-type impurities.

The active layer may be stacked on the first conductive-type semiconductor layer. In other words, the active layer may be positioned between the first conductive-type semiconductor layer and the second conductive-type semiconductor layer. In addition, the first conductive-type semiconductor layer and the active layer may form a mesa. A length L3 in a horizontal direction of the mesa may be smaller than a separation distance S between the first light emitting unit 100a and the second light emitting unit 100b. Accordingly, the light emission area of the light emitting units 100a and 100b can be maximized, and interference between the light emitting units 100a and 100b can be reduced, thereby improving the light emission efficiency of the light emitting apparatus 1.

A second conductive-type semiconductor layer may be stacked on an active layer and may be electrically connected to the device substrate 160. The second conductive-type semiconductor layer may include p-type impurities (e.g., Mg, Sr, Ba). In this case, the second conductive-type semiconductor layer may be a p-type semiconductor layer. However, this is merely an example, and the second conductive-type semiconductor layer may also include p-type impurities.

The light transmitting layer 112 may be stacked on the light emitting structure 111. In other words, the light transmitting layer 112 may be stacked on the second conductive-type semiconductor layer. The light transmitting layer 112 may be an insulating or conductive substrate for growing the first conductive-type semiconductor layer, the active layer, and the second conductive-type semiconductor layer. As an example, the light transmitting layer 112 may include at least one of a sapphire substrate, a silicon carbide substrate, a silicon substrate, a gallium nitride substrate, or an aluminum nitride substrate.

The electrode 113 may be electrically connected to the light emitting structure 111 and the device substrate 160. In other words, the electrode 113 may be electrically connected to the first conductive-type semiconductor layer and the device substrate 160, or may be electrically connected to the second conductive-type semiconductor layer and the device substrate 160. By such an electrode 113, electricity may be applied to the light emitting structure 111, and the light emitting structure 111 may emit light.

The lower reflection layer 300 may be disposed on the substrate 200 to reflect light. For example, the lower reflection layer 300 may reflect upward light reflected by the second reflection layer 140, or light transmitted through the spacer 150. The lower reflection layer 300 may be disposed on the substrate 200 so as to be disposed between the plurality of light emitting units 100 and outside the plurality of light emitting units 100. For example, at least a portion of the lower reflection layer 300 may be disposed between the first light emitting unit 100a and the second light emitting unit 100b. The lower reflection layer 300 may have different reflectance from, or the same reflectance as, at least one of the first reflection layer 130 or the second reflection layer 140. An area of the lower reflection layer 300 may be greater than the first reflection layer 130 and the second reflection layer 140, and may reflect upward the light that is reflected by the second reflection layer 140 or not reflected by the first reflection layer 130 and directed downward. Accordingly, the light extraction efficiency of the light emitting units 100a and 100b can be increased.

Meanwhile, with reference to FIG. 6, transmission layers 120 of the plurality of light emitting units 100 may be connected to each other and may be integrally formed. In other words, the transmission layer 120 of the first light emitting unit 100a and the transmission layer 120 of the second light emitting unit 100b may be connected to each other.

In addition, since a height D7 of the first reflection layer 130 according to the second embodiment may be smaller than a height D5 of the light transmitting layer 112, a refraction path of light may be secured, an amount of light may be increased, and light may be smoothly reflected in a lateral direction. Since the height D7 of the first reflection layer 130 may be smaller than a separation distance D6 between the light transmitting layer 112 and the second reflection layer 140, a light movement path may be secured and an emission angle may be adjusted. Since the height D7 of the first reflection layer 130 may be greater than a height D4 of the light emitting structure 111, reflectance of light may be secured. When the height D7 of the first reflection layer 130 is smaller than the height D4 of the light emitting structure 111, reflectance of light in the first reflection layer 130 may be reduced and an absorptance may be increased.

In addition, the height D7 of the first reflection layer 130 may be greater than or smaller than a height D8 of the second reflection layer 140. When the height D7 of the first reflection layer 130 is greater than the height D8 of the second reflection layer 140, reflectance of the first reflection layer 130 may be improved and an amount of light may be increased. When the height D7 of the first reflection layer 130 is smaller than the height D8 of the second reflection layer 140, reflectance of the second reflection layer 140 may be secured, thereby increasing an amount of light reflected to a side. Since the height D7 of the first reflection layer 130 may be smaller than a height D1 of the transmission layer 120, a refraction distance of light may be secured in the transmission layer 120. The height D7 of the first reflection layer 130 may be formed to be smaller than a height D9 of the lower reflection layer 300 disposed between the first light emitting unit 100a and the second light emitting unit 100b, so that reflectance of light in the lower reflection layer 300 may be secured.

The height D5 of the light transmitting layer 112 may be smaller than or greater than the separation distance D6 between the light transmitting layer 112 and the second reflection layer 140. When the height D5 of the light transmitting layer 112 is greater than the separation distance D6 between the light transmitting layer 112 and the second reflection layer 140, a reflection path of light may be secured, and a wide emission angle may be obtained. When the height D5 of the light transmitting layer 112 is smaller than the separation distance D6 between the light transmitting layer 112 and the second reflection layer 140, a reflection path of light may be narrowed, and the emission angle may be adjusted. The height D5 of the light transmitting layer 112 may be formed to be greater than the height D4 of the light emitting structure 111, so that a refraction path of light may be secured, and light may be transmitted from an upper surface or a side surface of the light transmitting layer 112 rather than the light emitting structure 111. The height D5 of the light transmitting layer 112 may be formed to be greater than the height D8 of the second reflection layer 140, so that a refraction path of light may be secured. Accordingly, interference in the optical paths of the light emitting units 100a and 100b can be reduced, and the light extraction efficiency of the light emitting units 100a and 100b can be increased.

In addition, the height D5 of the light transmitting layer 112 may be formed to be greater than or smaller than the height D1 of the transmission layer 120. When the height D5 of the light transmitting layer 112 is formed to be greater than the height D1 of the transmission layer 120, a refraction distance of light in the transmission layer 120 may be secured. When the height D5 of the light transmitting layer 112 is formed to be smaller than the height D1 of the transmission layer 120, the light emitting device 110 may be efficiently protected by the transmission layer 120. The height D5 of the light transmitting layer 112 may be formed to be greater than the height D9 of the lower reflection layer 300 disposed between the first light emitting unit 100a and the second light emitting unit 100b, so that a refraction path of light may be secured.

The separation distance D6 between the light transmitting layer 112 and the second reflection layer 140 may be formed to be greater than at least one of the height D4 of the light emitting structure 111 and the height D8 of the second reflection layer 140, so that a movement distance of light may be secured, and the emission angle may be widened. In addition, the separation distance D6 between the light transmitting layer 112 and the second reflection layer 140 may be formed to be greater than or smaller than the height D1 of the transmission layer 120. When the separation distance D6 between the light transmitting layer 112 and the second reflection layer 140 is formed to be greater than the height D1 of the transmission layer 120, a movement distance of light may be secured, the emission angle may be widened, and an amount of light may be improved. When the separation distance D6 between the light transmitting layer 112 and the second reflection layer 140 is formed to be smaller than the height D1 of the transmission layer 120, a refraction distance of light in the transmission layer 120 may be secured. The separation distance D6 between the light transmitting layer 112 and the second reflection layer 140 may be formed to be greater than the height D9 of the lower reflection layer 300 disposed between the first light emitting unit 100a and the second light emitting unit 100b, so that a movement distance of light may be secured, the emission angle may be widened, and an amount of light may be improved.

The height D4 of the light emitting structure 111 may be formed to be smaller than the height D8 of the second reflection layer 140, so that reflectance of light in the second reflection layer 140 may be secured. The height D4 of the light emitting structure 111 may be formed to be smaller than the height D1 of the transmission layer 120, so that a refraction distance of light may be secured, and the emission angle may be widened. The height D4 of the light emitting structure 111 may be formed to be smaller than the height D9 of the lower reflection layer 300 disposed between the first light emitting unit 100a and the second light emitting unit 100b, so that a movement distance of light may be secured, the emission angle may be widened, and an amount of light may be improved.

The height D8 of the second reflection layer 140 may be formed to be smaller than the height D1 of the transmission layer 120, so that a refraction distance of light may be secured and the emission angle may be widened. In addition, the height D8 of the second reflection layer 140 may be formed to be greater than the height D9 of the lower reflection layer 300 disposed between the first light emitting unit 100a and the second light emitting unit 100b, so that reflectance of light may be secured, but is not limited thereto. In other words, the height D8 of the second reflection layer 140 may be formed to be smaller than the height D9 of the lower reflection layer 300 disposed between the first light emitting unit 100a and the second light emitting unit 100b, Accordingly, some light may be transmitted through the upper surface, thereby adjusting an emission angle pattern and improving a sterilization efficiency or an insect trapping efficiency.

The height D1 of the transmission layer 120 may be formed to be greater than the height D9 of the lower reflection layer 300 disposed between the first light emitting unit 100a and the second light emitting unit 100b, so that a refraction distance of light may be secured.

A length L6 in a horizontal direction of the first reflection layer 130 may be formed to be greater than a length L4 in a horizontal direction of the light transmitting layer 112, so that a reflection region may be secured and light extraction efficiency may be increased. The length L6 in a horizontal direction of the first reflection layer 130 may be formed to be smaller than a separation distance between the spacer 150 and the light transmitting layer 112, so that interference by the spacer 150 may be minimized and light extraction efficiency may be increased. The length L6 in a horizontal direction of the first reflection layer 130 may be formed to be greater than a length L3 in a horizontal direction of the mesa, so that a reflection region may be secured and the light extraction efficiency may be increased. The length L6 in a horizontal direction of the first reflection layer 130 may be formed to be smaller than or greater than a length L7 in a horizontal direction of the second reflection layer 140, so that an emission angle may be adjusted. The length L6 in a horizontal direction of the first reflection layer 130 may be formed to be smaller than a length L5 in a horizontal direction of the transmission layer 120, so that the first reflection layer 130 may be protected from external impact by the transmission layer 120. The length L6 in a horizontal direction of the first reflection layer 130 may be formed to be smaller than the length L9 in a horizontal direction of the lower reflection layer 300 disposed between the first light emitting unit 100a and the second light emitting unit 100b, so that a reflection region of the lower reflection layer 300 may be secured and the light extraction efficiency may be increased. The length L6 in a horizontal direction of the first reflection layer 130 may be formed to be smaller than a length L8 in a horizontal direction of the device substrate 160, so that the first reflection layer 130 may be stably supported on the device substrate 160.

The length L4 in a horizontal direction of the light transmitting layer 112 may be formed to be smaller than or greater than a separation distance between the spacer 150 and the light transmitting layer 112. When the length L4 in a horizontal direction of the light transmitting layer 112 is formed to be smaller than the separation distance between the spacer 150 and the light transmitting layer 112, interference by the spacer 150 may be minimized and the light extraction efficiency may be increased. When the length L4 in a horizontal direction of the light transmitting layer 112 is formed to be greater than the separation distance between the spacer 150 and the light transmitting layer 112, the light emitting unit 100 may be miniaturized and the integration density of the light emitting unit 100 may be improved.

The length L4 in a horizontal direction of the light transmitting layer 112 may be formed to be greater than the length L3 in a horizontal direction of the mesa, so that a refraction path of light may be secured, and light may be transmitted from an upper surface or a side surface of the light transmitting layer 112 rather than the light emitting structure 111. The length L4 in a horizontal direction of the light transmitting layer 112 may be formed to be smaller than the length L7 in a horizontal direction of the second reflection layer 140, so that a reflection region of the second reflection layer 140 may be secured and light may be efficiently reflected downward and sideways to widen an emission angle. The length L4 in a horizontal direction of the light transmitting layer 112 may be formed to be smaller than the length L5 in a horizontal direction of the transmission layer 120, so that the light emitting device 110 may be efficiently protected. The length L4 in a horizontal direction of the light transmitting layer 112 may be formed to be smaller than the length L9 in a horizontal direction of the lower reflection layer 300 disposed between the first light emitting unit 100a and the second light emitting unit 100b, so that a reflection region of the lower reflection layer 300 may be secured and light extraction efficiency may be increased. The length L4 in a horizontal direction of the light transmitting layer 112 may be formed to be smaller than the length L8 in a horizontal direction of the device substrate 160, so that the light emitting device 110 may be stably designed.

A separation distance between the spacer 150 and the light transmitting layer 112 may be formed to be greater than the length L3 in a horizontal direction of the mesa, so that a movement distance of light may be secured and an emission angle may be widened. A separation distance between the spacer 150 and the light transmitting layer 112 may be formed to be smaller than the length L7 in a horizontal direction of the second reflection layer 140, so that a reflection region of the second reflection layer 140 may be widened and an emission angle may be widened. A separation distance between the spacer 150 and the light transmitting layer 112 may be formed to be smaller than the length L4 in a horizontal direction of the light transmitting layer 112, so that the light emitting device 110 and the first reflection layer 130 may be efficiently protected. A separation distance between the spacer 150 and the light transmitting layer 112 may be formed to be smaller than the length L9 in a horizontal direction of the lower reflection layer 300 disposed between the first light emitting unit 100a and the second light emitting unit 100b, so that a reflection region of the second reflection layer 140 or the lower reflection layer 300 may be secured and reflection efficiency may be increased.

The length L3 in a horizontal direction of the mesa may be formed to be smaller than the length L7 in a horizontal direction of the second reflection layer 140, so that a reflection region of the second reflection layer 140 may be secured and an emission angle may be efficiently widened. The length L3 in a horizontal direction of a mesa may be formed to be smaller than the length L5 in a horizontal direction of the transmission layer 120, so that the light emitting device 110 may be protected from an external environment. The length L3 in a horizontal direction of the mesa may be formed to be smaller than the length L9 in a horizontal direction of the lower reflection layer 300 disposed between the first light emitting unit 100a and the second light emitting unit 100b, so that a reflection region of the lower reflection layer 300 may be secured and light extraction efficiency may be improved.

The length L7 in a horizontal direction of the second reflection layer 140 may be formed to be smaller than the length L5 in a horizontal direction of the transmission layer 120, so that the second reflection layer 140 may be protected and may be stably disposed on the transmission layer 120. The length L7 in a horizontal direction of the second reflection layer 140 may be formed to be smaller than the length L9 in a horizontal direction of the lower reflection layer 300 disposed between the first light emitting unit 100a and the second light emitting unit 100b, so that a reflection region of the lower reflection layer 300 may be secured and light extraction efficiency may be increased.

The length L7 in a horizontal direction of the second reflection layer 140 may be formed to be smaller than the length L8 in a horizontal direction of the device substrate 160, so that the light emitting unit 100 may be stably designed. In addition, the length L7 in a horizontal direction of the second reflection layer 140 may be formed to extend by an extension length A extending in a horizontal direction outward from an edge of the light emitting device 110. In other words, an edge of the second reflection layer 140 may be spaced apart by the extension length A or more in a horizontal direction from an edge of the light emitting device 110.

The extension length A may be formed as in Equation 1 below in consideration of a region of about 120° which is an emission angle of the light emitting device 110.

$$A > \frac{D 6}{tan θ} \qquad [ Equation 1 ]$$

In Equation 1, θ may be formed to be 30° or less based on an emission angle of the light emitting device 110. In other words, by the definition of Pythagoras, the extension length A may be greater than a value obtained by dividing the separation distance D6 between the light transmitting layer 112 and the second reflection layer 140 by tan(30°). In addition, the length L7 in a horizontal direction of the second reflection layer 140 may be as in Equation 2 below.

$$L 7 \geq A + L 4 = D 6 \sqrt{3} + L 4 \qquad [ Equation 2 ]$$

The length L7 in a horizontal direction of the second reflection layer 140 may be longer than a distance obtained by adding the extension length A and the length L4 in a horizontal direction of the light transmitting layer 112. Through this, the length L7 in a horizontal direction of the second reflection layer 140 may sufficiently cover a light emission area directed upward among the emission pattern of the light emitting device 110, thereby increasing an amount of light emitted to a side.

The length L5 in a horizontal direction of the transmission layer 120 may be formed to be smaller than the length L9 in a horizontal direction of the lower reflection layer 300 disposed between the first light emitting unit 100a and the second light emitting unit 100b, so that a reflection region of the lower reflection layer 300 may be secured and light may be efficiently reflected upward. The length L5 in a horizontal direction of the transmission layer 120 may be formed to be smaller than the length L8 in a horizontal direction of the device substrate 160, so that the light emitting unit 100 may be stably designed.

With reference to FIG. 6, the length L5 in a horizontal direction of the transmission layer 120 may cover all of a plurality of light emitting devices 110, and may simplify a process and reduce a design difficulty.

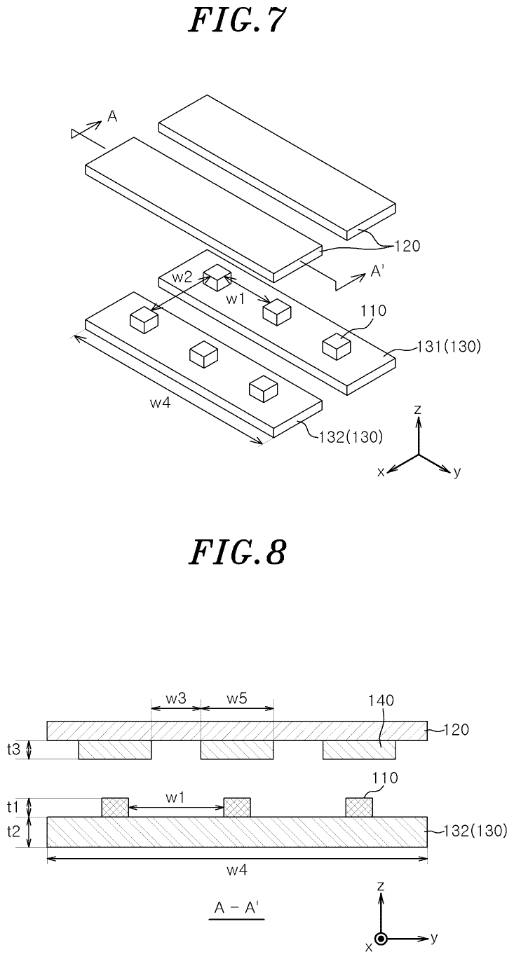

Hereinafter, with reference to FIGS. 7 and 8, a light emitting apparatus 1 according to a third embodiment of the present invention will be described.

In describing the third embodiment, a difference lies in that the first reflection layer 130 may be formed in plural, and such a difference will be mainly described.

A plurality of light emitting devices 110 may be disposed on the plurality of first reflection layers 130. The plurality of first reflection layers 130 may be formed to be elongated in a first direction (y-axis direction in FIG. 8) and may be disposed to be spaced apart from each other in a second direction cross the first direction (x-axis direction in FIG. 8). As such, the area for heat diffusion within the light emitting units 100a and 100b can be increased, thereby improving the heat dissipation efficiency of the light emitting units 100a and 100b. The plurality of first reflection layers 130 may include a first sub-reflection layer 131 and a second sub-reflection layer 132.

The first sub-reflection layer 131 may extend in the first direction, a portion of the plurality of light emitting devices 110 may be disposed thereon. A plurality of light emitting devices 110 disposed on the first sub-reflection layer 131 may be disposed to be spaced apart from each other in the first direction.

The second sub-reflection layer 132 may be disposed to be spaced apart in the second direction from the first sub-reflection layer and may be elongated in the first direction such that another portion of the plurality of light emitting devices 110 may be disposed thereon. A separation distance w1 in the first direction between the plurality of light emitting devices 110 may be smaller than a separation distance w2 in the second direction between the plurality of light emitting devices, thereby increasing the light uniformity in the first direction.

The transmission layer 120 may be formed in plural corresponding to the plurality of first reflection layers 130. The plurality of transmission layers 120 may be formed to extend in the first direction, and may be disposed to be spaced apart from each other in the second direction. An extension length of the transmission layer 120 may be the same as an extension length w4 of the first reflection layer 130, but is not limited thereto. The extension length of the transmission layer 120 may be formed such that one of the extension lengths w4 of the first reflection layer 130 is longer than the other, and may protect the first reflection layer 130 from an external environment.

The second reflection layer 140 may be formed in plural and may be disposed on at least one of the transmission layers 120 so as to correspond to positions of the plurality of light emitting devices 110. A portion of the plurality of second reflection layers 140 may be disposed in one region of at least one of the transmission layers 120, and another portion of the plurality of second reflection layers 140 may be disposed to be spaced apart in another region of at least one of the transmission layers 120. A separation distance w3 in the first direction of the plurality of second reflection layers 140 may be smaller than a length w5 in the horizontal direction of the second reflection layer 140. The separation distance w3 in the first direction of the plurality of second reflection layers 140 may be smaller than the separation distance w1 in the first direction between the plurality of light emitting devices 110, and through this, light directed upward may be reflected to a side to widen an emission angle.

In addition, a height t3 of the second reflection layer 140 may be formed to be different from at least one of a height t2 of the first reflection layer 130 or a height t1 of the light emitting device 110. The height t3 of the second reflection layer 140 may be formed to be smaller than the height t2 of the first reflection layer 130, and may reflect a portion of light reflected downward again upward, but is not limited thereto, and the height t3 of the second reflection layer 140 may be formed to be greater than the height t2 of the first reflection layer 130, thereby increasing the reflectance toward the lower direction. In addition, the height t1 of the light emitting device 110 may be formed to be smaller than at least one of the height t3 of the second reflection layer 140 or the height t2 of the first reflection layer 130, but is not limited thereto, and the height t1 of the light emitting device 110 may be formed to be greater than at least one of the height t3 of the second reflection layer 140 or the height t2 of the first reflection layer 130.

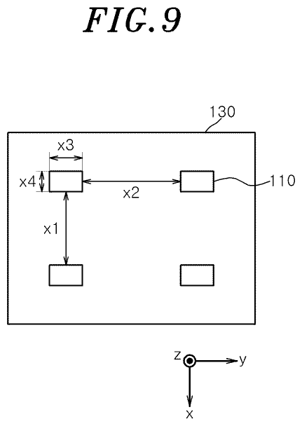

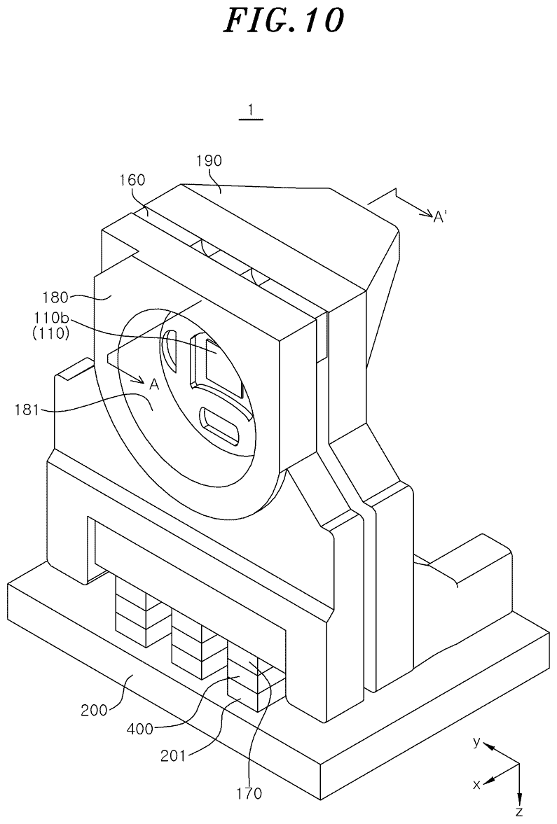

Hereinafter, with reference to FIG. 9, a light emitting apparatus 1 according to a fourth embodiment will be described.

In describing the fourth embodiment, a difference lies in that a plurality of light emitting devices 110 may share one first reflection layer 130, and such a difference will be mainly described.

The plurality of light emitting devices 110 may be spaced apart from each other and may share the first reflection layer 130. For example, the plurality of light emitting devices 110 may be disposed in N rows and M columns on the first reflection layer 130 and may respectively generate light. In other words, the plurality of light emitting devices 110 may be arranged in an N×M matrix and may respectively generate light. A separation distance x1 in a first direction (x-axis direction in FIG. 10) between the plurality of light emitting devices 110 may be smaller than a separation distance x2 in a second direction cross the first direction (y-axis direction in FIG. 10) between the plurality of light emitting devices 110.

In addition, a length x4 in the first direction of the plurality of light emitting devices 110 may be formed to be smaller than a length x3 in the second direction of the plurality of light emitting devices 110. In other words, the plurality of light emitting devices 110 may be formed in a rectangular shape when viewed in a vertical direction (z-axis direction in FIG. 10), but is not limited thereto.

In this case, an area of the first reflection layer 130 may be greater than an area arranged in the N×M matrix. A length in the first direction of the first reflection layer 130 may be greater than a sum of x1 and x4. A length in the first direction of the first reflection layer 130 may be greater than a sum of x3 and x2. A minimum length extending laterally from an edge of the first reflection layer 130 to the light emitting device 110 may be greater than the length x4 in the second direction of the light emitting device 110. The plurality of second reflection layers 140 may cover all of the light emitting devices 110, so that light generated upward from the light emitting devices 110 may be laterally reflected, thereby efficiently widening an emission angle.

Hereinafter, a light emitting apparatus 1 according to a fifth embodiment will be described with reference to FIGS. 10 to 13.

In describing the fifth embodiment, there is a difference in that different light is generated from a plurality of light emitting devices 110a and 110b, and the explanation will focus mainly on this difference.

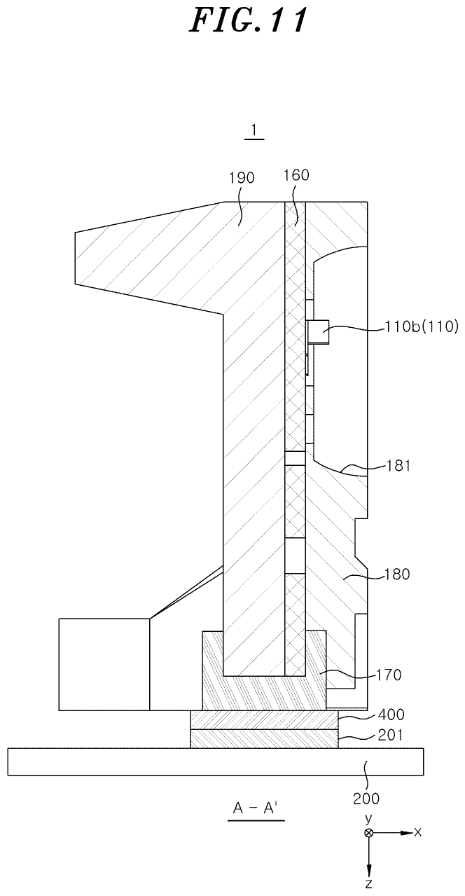

Referring to FIGS. 10 and 11, the light emitting apparatus 1 according to the fifth embodiment of the present invention can be mounted to an insect trap (not shown) to emit light that attracts insects into the trap. The light emitting apparatus 1 may be arranged inside the insect trap. In other words, the light emitting apparatus 1 can emit light from within the trap, attracting insects outside toward the interior of the trap.

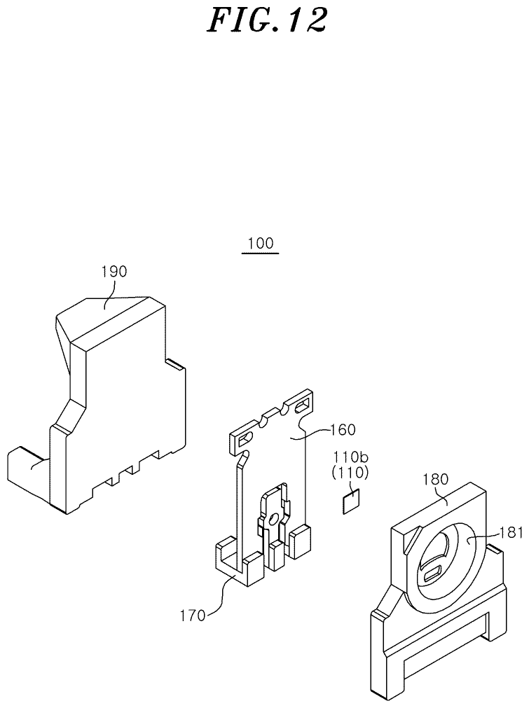

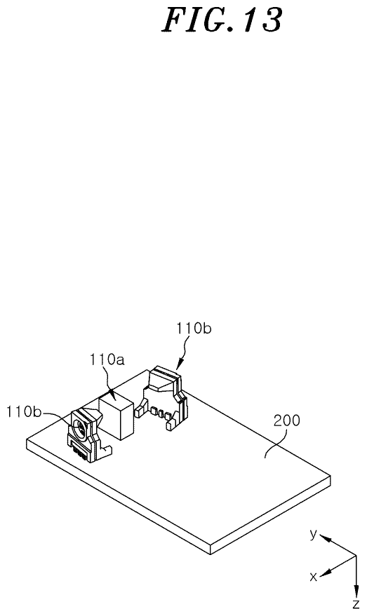

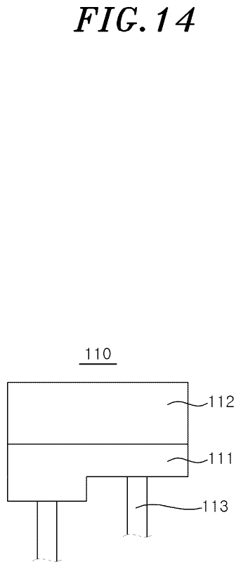

Referring further to FIGS. 12 and 13, a light emitting unit 100 can emit light. The light emitting unit 100 is electrically connected to an electrical circuit of a substrate 200 and can emit light by receiving power from an external source through the circuit. The light emitting unit 100 may further include a terminal 170, a first frame 180, and a second frame 190.

Referring to FIG. 14, a light emitting device 110 can emit light. The light emitting device 110 may be provided in plural. The plurality of light emitting devices 110a and 110b may include a first light emitting device 110a and a second light emitting device 110b that emit light of different wavelengths. The plurality of light emitting devices 110a and 110b may include a light emitting structure 111, a light transmission layer 112, and an electrode 113.

The first light emitting device 110a may emit light with a wavelength different from that of the second light emitting device 110b. For example, the first light emitting device 110a may emit visible light. In more detail, it may emit light in a wavelength range of 400 nm to 500 nm. Whether or not visible light is emitted from the first light emitting device 110a allows the user to recognize whether the insect trap is operating. As one example, when visible light is emitted from the first light emitting device 110a, the user can recognize that the insect trap is operating. As another example, when visible light is not emitted from the first light emitting device 110a, the user can recognize that the insect trap is operating. If the first light emitting device 110a emits light with a wavelength of 500 nm or more, insects' preference for the light may decrease, and the insect trapping efficiency of the trap may be reduced. In addition, the wavelength difference between the first light emitting device 110a and the second light emitting device 110b may be 20 nm or more. Through this, interference between the first light emitting device 110a and the second light emitting device 110b may not occur.

The first light emitting device 110a may be disposed at the center of the substrate 200. As one example, it may be arranged such that an imaginary line passing through the center of the first light emitting device 110a and parallel to the element substrate 160 forms a perpendicular angle with the substrate 200.

The second light emitting device 110b may emit light of a different wavelength than the first light emitting device 110a. For example, the second light emitting device 110b may emit ultraviolet rays. More specifically, the second light emitting device 110b may emit light with a wavelength between 315 nm and 400 nm. The ultraviolet rays emitted from the second light emitting device 110b may be a wavelength of light to which insects are highly sensitive. In other words, the ultraviolet rays emitted from the second light emitting device 110b can attract insects.

The second light emitting device 110b may be arranged in a direction facing the side of the first light emitting device 110a. Such second light emitting devices 110b may be provided in plural. More specifically, there may be two second light emitting devices 110b. The plurality of second light emitting devices 110b may be arranged so as to face the sides around the first light emitting device 110a as the center. As one example, the second light emitting device 110b may be arranged to face the left side of the first light emitting device 110a. As another example, the second light emitting device 110b may be arranged to face the right side of the first light emitting device 110a.

The plurality of second light emitting devices 110b may emit light in different directions. For example, the plurality of second light emitting devices 110b may emit light in directions away from the first light emitting device 110a. As one example, the second light emitting device 110b arranged to face the left side of the first light emitting device 110a may emit light to the left. As another example, the second light emitting device 110b arranged to face the right side of the first light emitting device 110a may emit light to the right. In addition, the second light emitting device 110b may be arranged to face the sides of the light emitting devices 110a and 110b. Accordingly, optical interference between the light emitting devices 110a and 110b may be reduced, thereby improving the insect trapping efficiency.

The first light emitting device 110a can emit light toward a first direction parallel to the substrate 200. Further, the second light emitting device 110b can emit light toward a second direction that is parallel to the substrate 200 and parallel to the first direction. In other words, the main emission direction, the first direction, of light from the first light emitting device 110a can be substantially perpendicular to the main emission direction, the second direction, of light from the second light emitting device 110b. As such, optical interference caused by light and heat from the second light emitting device 110b on the first light emitting device 110a can be reduced.

The light emitting structure 111 can emit light. This light emitting structure 111 may include a first conductive-type semiconductor layer, an active layer, and a second conductive-type semiconductor layer. The wavelength of light emitted from the light emitting structure 111 may be blue light and ultraviolet light. As one example, the first light emitting device 110a can generate a blue light wavelength in the light emitting structure 111 and emit visible light externally. As another example, the second light emitting device 110b can generate an ultraviolet wavelength in the light emitting structure 111 and emit ultraviolet light externally. The light emitting devices 110a, 110b can be arranged on the device substrate 160.

The device substrate 160 can be arranged on the upper side of the terminal 170. As one example, the device substrate 160 can be arranged to connect to the side of the terminal 170. Additionally, the device substrate 160 can be arranged in a direction crossing the substrate 200. When the device substrate 160 is arranged in a direction crossing the substrate 200 and the light emitting device 110b is connected to the device substrate 160, the light generated from the light emitting device 110b can be emitted outward.

The device substrate 160 can dissipate heat generated from the light emitting devices 110a and 110b to the outside. In other words, heat generated from the light emitting devices 110a and 110b can diffuse along the device substrate 160, and while diffusing, the heat can be emitted externally. Heat is released through the device substrate 160, improving the thermal management performance of the light emitting apparatus 1. The device substrate 160 can be provided in plural. Referring again to FIG. 12, the device substrate 160 can be formed to extend in the y-axis direction. The length of the device substrate 160 in the y-axis direction may be longer than the length in the x-axis direction. This improves the efficiency of heat emission to the outside through the device substrate 160.

The terminal 170 can electrically connect the substrate 200 to the device substrate 160. In other words, the terminal 170 may be electrically connected to the device substrate 160 or to the substrate 200. By the terminal 170, current may be applied from the substrate 200 to the device substrate 160, causing the light emitting devices 110a and 110b to emit light. The terminal 170 may have a bent shape surrounding one edge of the device substrate 160 and the first and second frames 180 and 190. The terminal 170 may be bent in a direction parallel to the z-axis. As one example, the terminal 170 may have a “⊏” shape with two bends. As another example, the terminal 170 may have an L shape with one bend. By being bent, the terminal 170 can increase the contact area between the terminal 170 and the substrate 200, thereby increasing the thermal capacity of the terminal 170. The length extended by the bend of the terminal 170 in the direction parallel to the z-axis may be from two times to less than ten times the thickness of the device substrate 160. By thickening the terminal 170, the thermal capacity of the terminal 170 increases, reducing bottleneck phenomena inside the terminal 170. The groove formed in the terminal 170 may accommodate the device substrate 160 and the second frame 190.

The first frame 180 can support the device substrate 160. The first frame 180 may be arranged outward in a horizontal direction parallel to the substrate 200. In other words, the first frame 180 may be arranged on one side of the device substrate 160. A hole may be formed on the inner side of the first frame 180. When the first frame 180 and the device substrate 160 are connected, the light emitting devices 110a and 110b arranged on the device substrate 160 may be arranged inside the hole formed in the first frame 180. The light emitting devices 110a and 110b arranged in the hole inside the first frame 180 form an open space around the light emitting devices 110a and 110b, reducing interference between optical emission paths. The first frame 180 may be provided with a reflector 181.

The reflector 181 can reflect light. In other words, the reflector 181 can reflect light emitted from the light emitting devices 110a and 110b to increase the amount of light directed in one direction. The reflector 181 may have a circular shape surrounding the light emitting devices 110a and 110b. In other words, the reflector 181 is arranged spaced apart from the light emitting devices 110a and 110b and may be formed along a circular circumference. The reflector 181 can reflect light emitted from the light emitting devices 110a and 110b in a specific direction, improving the light condensing and directivity of the light emitting unit 100, thereby improving the light emission efficiency of the light emitting apparatus 1. The reflector 181 can reflect light directed in the z-axis direction to the x-axis direction. As such, the light extraction efficiency of the light emitting device 110b can be improved.

The second frame 190 can support the device substrate 160. The second frame 190 may be arranged inward in a horizontal direction parallel to the substrate 200. In other words, the second frame 190 may be connected to a rear surface of the device substrate 160. The second frame 190 may be arranged above the terminal 170. The second frame 190 may be surrounded by the terminal 170. As one example, one edge of the second frame 190 may be surrounded by the terminal 170. The second frame 190 arranged together with the device substrate 160 in the groove of the terminal 170 can stably fix the light emitting unit 100.

A circuit electrode 201 may be provided on the substrate 200. The circuit electrode 201 may be electrically connected to a connector 400. In other words, the circuit electrode 201 can be electrically connected to the light emitting unit 100 via the connector 400. The circuit electrode 201 may be formed as an area extended in the y-axis direction. This improves heat diffusion efficiency within the substrate 200 and increases the heat emission efficiency of the substrate 200.

The connector 400 is arranged between the substrate 200 and the light emitting unit 100 and electrically connected to the circuit electrode 201 and the light emitting unit 100. The connector 400 can connect the substrate 200 and the light emitting unit 100. This connector 400 may be a fusible metal or metal alloy.

Hereinafter, the operation and effect of the light emitting apparatus 1 according to the fifth embodiment will be described.

The light emitting apparatus 1 can be connected to an insect trap. When current is applied to the substrate 200, current can be supplied to the light emitting unit 100 through the circuit electrode 201 and connector 400. When current is applied to the light emitting unit 100, light can be generated from the light emitting unit 100. The first light emitting device 110a can emit visible light. The user can recognize the operation of the insect trap by perceiving the visible light emitted from the first light emitting device 110a. The second light emitting device 110b can emit ultraviolet light. Insects flying in the air outside the insect trap can recognize the ultraviolet light emitted from the second light emitting device 110b and be attracted to the insect trap. In other words, the insects outside are guided by the ultraviolet light from the second light emitting device 110b and flow into the insect trap. The insect trap can remove insects flowing inside by applying high voltage to kill or by passing high current through an electrode mesh, or can capture insects with an adhesive sheet.

The examples of the present disclosure have been described above as specific embodiments, but these are only examples, and the present disclosure is not limited thereto, and should be construed as having the widest scope according to the technical spirit disclosed in the present specification. A person skilled in the art may combine/substitute the disclosed embodiments to implement a pattern of a shape that is not disclosed, but it also does not depart from the scope of the present disclosure. In addition, those skilled in the art can easily change or modify the disclosed embodiments based on the present specification, and it is clear that such changes or modifications also belong to the scope of the present disclosure.

[Explanation of Symbols]

| | |
|---|---|
| 1: light emitting apparatus | 2: ship |
| 100: light emitting unit | 100a: first light emitting unit |
| 100b: second light emitting unit | 110: light emitting device |
| 110a: first light emitting device | 110b: second light emitting device |
| 111: light emitting structure | 112: light transmitting layer |
| 113: electrode | 120: transmission layer |
| 130: first reflection layer | 131: first sub-reflection layer |
| 132: second sub-reflection layer | 140: second reflection layer |
| 150: spacer | 160: device substrate |
| 170: terminal | 180: first frame |
| 181: reflector | 190: second frame |
| 200: substrate | 201: circuit electrode |
| 300: lower reflection layer | 400: connector |

1. A light emitting apparatus, comprising:
a light emitting unit; and
a substrate in which the light emitting unit is disposed,
wherein the light emitting unit generates light so that a main emission direction faces a horizontal direction parallel to the substrate.

2. The light emitting apparatus of claim 1, wherein the light emitting unit comprises a plurality of light emitting devices, and
the plurality of light emitting devices includes: a first light emitting device that emits visible light, and a second light emitting device that emits ultraviolet light.

3. The light emitting apparatus of claim 2, wherein the first light emitting device is disposed at a center of the substrate, and
the second light emitting device is disposed in a direction facing a side of the first light emitting device.

4. The light emitting apparatus of claim 2, wherein the first light emitting device is arranged to emit the light in a first direction parallel to the substrate, and
the second light emitting device is arranged to emit the light in a second direction that is parallel to the substrate and crosses the first direction.

5. The light emitting apparatus of claim 2, wherein the second light emitting device is disposed in a direction facing a side of the first light emitting device.

6. The light emitting apparatus of claim 1, wherein the light emitting unit includes:
a device substrate; and
a terminal electrically connecting the device substrate and the substrate.

7. The light emitting apparatus of claim 6, wherein the light emitting unit further comprises a second frame on which the device substrate is disposed, and
the terminal has a shape surrounding one edge of the device substrate and one edge of the second frame.

8. The light emitting apparatus of claim 1, wherein the light emitting unit further comprises:
a light emitting device;
a device substrate on which the light emitting device is mounted; and
a first frame on which the device substrate is disposed,
wherein the first frame is provided with a reflector that reflects light emitted from the light emitting device.

9. The light emitting apparatus of claim 8, wherein the reflector has a circular shape surrounding the light emitting device.

10. The light emitting apparatus of claim 1, wherein the light emitting unit further comprises:
a light emitting device;
a first reflection layer on which the light emitting device is disposed and which is configured to reflect light;
a transmission layer disposed above the light emitting device and configured to transmit light; and
a second reflection layer disposed to be spaced apart from the light emitting device by the transmission layer and configured to reflect light.

11. The light emitting apparatus of claim 10, wherein a reflectivity of the second reflection layer is equal to or greater than a reflectivity of the first reflection layer,
a height of the first reflection layer is less than a separation distance between the light emitting device and the second reflection layer,
the height of the first reflection layer is less than a height of the transmission layer,
a height of the second reflection layer is less than the height of the transmission layer,
a length of the first reflection layer in the horizontal direction is greater than a length of the light emitting device in the horizontal direction, and
the length of the first reflection layer in the horizontal direction is less than a length of the transmission layer in the horizontal direction.

12. The light emitting apparatus of claim 1, wherein the light emitting unit further comprises:
a light emitting device;
a transmission layer disposed above the plurality of light emitting devices to transmit light;
a first reflection layer on which the plurality of light emitting devices are disposed and which reflects light, wherein the transmission layer is arranged to be spaced apart from the light emitting device; and
a spacer that scatters light,
wherein a separation distance between the light emitting device and the spacer is greater than a length of the first reflection layer in the horizontal direction.

13. The light emitting apparatus of claim 1, wherein the light emitting unit further comprises:
a plurality of light emitting devices;
a first reflection layer on which the plurality of light emitting devices are arranged;
a transmission layer disposed above the plurality of light emitting devices to transmit light; and
a plurality of second reflection layers arranged on the transmission layer and spaced apart from the plurality of light emitting devices and to reflect light.

14. The light emitting apparatus of claim 13, wherein the light emitting device further comprises:
a light emitting structure that generates light; and
a light transmission layer laminated on the light emitting structure to transmit the light generated from the light emitting structure, and
wherein a height of the first reflection layer is greater than a height of the light emitting structure.

15. The light emitting apparatus of claim 14, wherein a separation distance between the light transmission layer and the second reflection layer is greater than the height of the light emitting structure,
a height of the light transmission layer is greater than a height of the second reflection layer,
the height of the light emitting structure is less than the height of the light transmission layer, and
the height of the light emitting structure is less than the height of the second reflection layer.

16. The light emitting apparatus of claim 15, wherein the first reflection layer includes a plurality of first reflection layers,
the plurality of first reflection layers includes:
a first sub-reflection layer elongating in a first direction, and supporting one of the plurality of light emitting devices; and
a second sub-reflection layer spaced apart from the first sub-reflection layer in a second direction crossing the first direction, elongated in the first direction, and on which another of the plurality of light emitting devices is disposed,
one of the plurality of light emitting devices are spaced apart from each other along the first direction on the first sub-reflection layer,
another of the plurality of light emitting devices are spaced apart from each other along the first direction on the second sub-reflection layer,
a distance between the light emitting devices in the first direction is smaller than a distance between the light emitting devices in the second direction, and
the transmission layers of the plurality of light emitting devices are integrally formed by being connected to each other.

17. A light emitting apparatus, comprising:
a plurality of light emitting units;
a substrate on which the plurality of light emitting units are disposed; and
a lower reflection layer disposed on the substrate such that at least a portion of the lower reflection layer is located between the plurality of light emitting units,
wherein each of the plurality of light emitting units includes:
a device substrate;
a light emitting device disposed on the device substrate;
a first reflection layer disposed between the light emitting device and the device substrate to reflect light;
a transmission layer disposed above the light emitting device to transmit light; and
a second reflection layer disposed on the transmission layer so as to be spaced apart from the light emitting device to reflect light, and
wherein a height of the lower reflection layer is greater than a height of the first reflection layer.

18. Alight emitting apparatus, comprising:
a light emitting unit; and
a substrate on which the light emitting unit is disposed,
wherein the light emitting unit includes a light emitting device,
heat generated from the light emitting unit is diffused in a second direction parallel to the substrate and released in a third direction crossing the substrate, and
the second direction crosses the third direction.

19. The light emitting apparatus of claim 18, wherein the light emitting unit further comprises a device substrate,
the device substrate is disposed in a direction crossing the substrate, and
the heat is released to an outside along the device substrate

20. A light emitting apparatus, comprising:
a light emitting unit; and
a substrate on which the light emitting unit is disposed,
wherein the light emitting unit emits light in a main emission direction that is parallel to a first direction of the substrate, and is configured to emit the light in a second direction parallel to the substrate, and
the first direction crosses the second direction.
